(19) United States
(12) Patent Application Publication
(10) Pub. No.: US 2005/0212100 A1
(43) Pub. Date: Sep. 29, 2005

(54) Semiconductor device for optical communication and manufacturing method therefor

(75) Inventor: Tomio Fujimoto, Nara-ken (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/087,860

(22) Filed: Mar. 24, 2005

(30) Foreign Application Priority Data
Mar. 26, 2004 (JP) P2004-091768

(51) Int. Cl. H01L 23/495

(52) U.S. Cl. 257/666

(57) ABSTRACT

A lead frame, a photodetector mounted on the lead frame and a signal processing section that is mounted on the lead frame and electrically connected to the photodetector are provided. A first sealing portion fabricated of a translucent resin that seals the photodetector and the signal processing section is provided. A second sealing portion fabricated of a conductive resin that covers the first sealing portion is provided. The conductive resin, which constitutes the second sealing portion, is made of polycarbonate and a conductive additive.

This nonprovisional application claims priority under 35 U.S.C. §119(a) on Patent Application No. 2004-091768 filed in Japan on Mar. 26, 2004, the entire contents of which are hereby incorporated by reference.

### BACKGROUND OF THE INVENTION

The present invention relates to a semiconductor device for optical communication having a photodetector and a signal processing section and to a manufacturing method therefor. A remote control light receiving unit, which is attached to an electronic equipment of, for example, a TV (television set), a VTR (video tape recorder), an audio component or an air conditioner and generates a control signal for controlling the operation of the electronic equipment by receiving an infrared ray signal from a transmitter, can be enumerated as the semiconductor device for optical communication.

A general remote control light receiving unit is constituted by sealing a photodetector chip mounted on a lead frame and a signal processing IC (Integrated Circuit) chip with a translucent resin. Signal input and output terminals, which are constructed of part of the lead frame, project outwardly of the translucent resin and electrically connected to a mounting board. The remote control light receiving unit of this kind receives a control signal of a variety of electronic equipments transmitted from the transmitter by infrared rays in operation. The signal transmitted by the infrared rays is very feeble. Therefore, an amplifier of a high gain is built in the signal processing IC chip, and the amplifier amplifies the optical signal of the infrared rays, converts the optical signal into a digital signal and outputs the resulting signal. Therefore, the remote control light receiving unit is very sensitive to electromagnetic noises.

As a measure against the electromagnetic noises, it is known to cover the translucent resin with a metal shield casing and electrically connect an end portion of the shield casing to the ground terminal of the mounting board. However, the above arrangement has problems of an increase in the number of processes for attaching the shield casing, the cost of the shield casing itself, restrictions on the degrees of freedom of mounting on the board depending on the shape of the shield casing and so on.

Accordingly, JP H09-84162A proposes a system in which the photodetector chip and the signal processing IC chip are sealed with a translucent resin and thereafter the region of the translucent resin except for the light receiving lens portion and the surface from which the signal input and output terminals project is covered with a conductive resin in place of the shield casing. In order to ground the conductive resin, a ground terminal constructed of part of the lead frame is projected from the translucent resin and electrically connected to the conductive resin. Moreover, the first patent document further discloses a technique for covering the light receiving lens portion of the translucent resin with a metal mesh in order to suit the semiconductor device for optical communication to an environment where large electromagnetic noises exist.

However, according to the system of JP H09-84162A, when an inappropriate one is used as the material of the conductive resin, the problems of:
(a) the formation of the conductive resin cannot be satisfactorily achieved, so that productivity is not good;
(b) the conductivity of the conductive resin is poor, and the electromagnetic noise shielding effect is insufficient; and
(c) appearance and conductivity are changed (deteriorated) by heat applied during mounting particularly at the time of soldering and so on occur.

### SUMMARY OF THE INVENTION

Accordingly, it is an object of the present invention to provide a semiconductor device for optical communication excellent in productivity, electromagnetic noise shielding effect and reliability (including heat resistance, and it is the same hereinafter).

Moreover, the above described construction, in which the light receiving lens portion of the translucent resin is covered with another member like a metal mesh in order to suit the semiconductor device for optical communication to the environment where large electromagnetic noises exist as in JP H09-84162A, costs high.

Accordingly, another object of the present invention is to provide a manufacturing method of the semiconductor device for optical communication capable of satisfactorily forming the mesh section for covering the light receiving lens portion of a conductive resin.

In order to solve the problems, the present inventor has repetitively conducted experiments and consequently obtained a semiconductor device for optical communication excellent in productivity, electromagnetic noise shielding effect and reliability (the experimental results will be described in detail later).

The semiconductor device for optical communication of the present invention comprises:
a lead frame;
a photodetector mounted on the lead frame;
a signal processing section that is mounted on the lead frame and electrically connected to the photodetector;
a first sealing portion that is fabricated of a translucent resin and seals the photodetector and the signal processing section; and
a second sealing portion that is fabricated of a conductive resin and covers the first sealing portion, wherein the conductive resin constituting the second sealing portion is made of polycarbonate and a conductive additive.

In one embodiment of the semiconductor device for optical communication, the conductive additive is a carbon fiber.

In one embodiment of the semiconductor device for optical communication, the conductive resin has a carbon fiber content of not lower than 15%.

In one embodiment of the semiconductor device for optical communication, the second sealing portion should preferably cover the portion of the exterior surface of the first sealing portion except for the surface from which the signal input and output terminals constructed of part of the lead frame project outwardly of the first sealing portion. The reason for the above is to prevent the signal input and output terminals from becoming electrically short-circuited to the second sealing portion.

The content of the carbon fiber as a conductive additive should preferably be not higher than 30% from the viewpoint of making satisfactory formation of the second sealing portion.

In one embodiment of the semiconductor device for optical communication, the ground terminal constructed of part of the lead frame should preferably be projected from the first sealing portion and electrically connected to the second sealing portion. In this case, no other member is required to be provided in order to ground the second sealing portion. Therefore, the semiconductor device for optical communication becomes costs low, and the degrees of freedom of mounting on the board is improved.

Moreover, in one embodiment of the semiconductor device for optical communication, a convex light receiving lens portion is provided in a portion of an exterior surface of the first sealing portion facing the photodetector, and the second sealing portion has a mesh section that covers a convex surface of the light receiving lens portion in a mesh form.

In the one embodiment of the semiconductor device for optical communication, the mesh section of the second sealing portion covers the convex surface of the light receiving lens portion in a mesh form. Therefore, light (infrared rays or the like) can be made incident on the photodetector through the intervals (meshes) of the mesh section and the light receiving lens portion, while electromagnetic noises can be shielded by the mesh section made of the conductive resin. Therefore, the semiconductor device for optical communication can be suited to the environment where large electromagnetic noises exist. Moreover, part of the second sealing portion constitutes the mesh section, and therefore, the semiconductor device for optical communication is manufactured at lower cost than when another member like the metal mesh is employed.

The manufacturing method of the semiconductor device for optical communication of the present invention comprises:
mounting a photodetector and a signal processing section on a lead frame and electrically connecting the signal processing section to the photodetector;
fabricating a first sealing portion that is made of a translucent resin and has a convex light receiving lens portion by sealing the photodetector and the signal processing section with the translucent resin; and
fabricating a second sealing portion that is made of a conductive resin and has a mesh section for covering a convex surface of the light receiving lens portion in a mesh form by injecting the conductive resin to a periphery of the first sealing portion by using a mold,
the mold having a liner in a portion corresponding to a vertex of the light receiving lens portion.

The mesh section has the mesh form that is minute and curved along the convex surface of the light receiving lens portion. Therefore, generally speaking, it is difficult to fabricate the mesh section by resin molding. The above is because, when the resin is injected into the mold, bubbles are left in meshed grooves of the mold which are corresponding to the mesh section, and the resin hardly enters the grooves.

According to the manufacturing method of the semiconductor device for optical communication of the present invention, the mold has a liner in a portion corresponding to the vertex of the light receiving lens portion. Therefore, when the conductive resin is injected into the mold in the process of fabricating the second sealing portion, air escapes from a minute gap between the main body of the mold and the liner. Therefore, the conductive resin successfully flows around the periphery of the light receiving lens portion, and the mesh section is accurately formed.

In another aspect, the manufacturing method of the semiconductor device for optical communication of the present invention comprises:
mounting a photodetector and a signal processing section on a lead frame and electrically connecting the signal processing section to the photodetector;
fabricating a first sealing portion that is made of a translucent resin and has a convex light receiving lens portion by sealing the photodetector and the signal processing section with the translucent resin; and
fabricating a second sealing portion that is made of a conductive resin and has a mesh section for covering a convex surface of the light receiving lens portion in a mesh form by injecting the conductive resin to a periphery of the first sealing portion by using a mold,
the mold having a resin injection gate facing the light receiving lens portion on a side opposite from a surface from which signal input and output terminals comprised of part of the lead frame project outwardly of the first sealing portion.

According to the manufacturing method of the semiconductor device for optical communication of the present invention, the resin injection gate of the mold faces the light receiving lens portion in a position comparatively near to the light receiving lens portion. Therefore, when the conductive resin is injected through the gate into the mold in the process of fabricating the second sealing portion, the conductive resin easily flows around the periphery of the light receiving lens portion. Therefore, the fabrication accuracy of the mesh section is improved.

In one embodiment of the manufacturing method of the semiconductor device for optical communication, the resin injection gate is inclined back and forth so as to inject a resin in a direction from a peripheral edge portion to a vertex of the light receiving lens portion.

The “back and forth” are defined by that the side on which the light receiving lens portion of the first sealing portion is provided, i.e., the side on which light is incident is assumed to be the “forth”.

According to the manufacturing method of the semiconductor device for optical communication of the one embodiment, when the conductive resin is injected through the gate into the mold in the process of fabricating the second sealing portion, the conductive resin is injected from the peripheral edge portion to the vertex of the light receiving lens portion. Therefore, the conductive resin easily flows from the peripheral edge portion to the vertex of the light receiving lens portion, and the fabrication accuracy of the mesh section is further improved.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1A is a view schematically showing a cross section of one embodiment of the semiconductor device for optical communication of the present invention; FIG. 1B is a view schematically showing another cross section of the same device;

FIG. 2 is a view of a modification example of the semiconductor device for optical communication viewed from the front;

FIG. 3 is a view for explaining a second sealing process using a metal mold for manufacturing the semiconductor device for optical communication of FIG. 2; and

FIG. 4 is a view showing the experimental results of the conductive resin that constitutes the second sealing portion.

### DETAILED DESCRIPTION OF THE PREFERRED EMBODIMENTS

The present invention will be described in detail below on the basis of embodiments shown in the drawings.

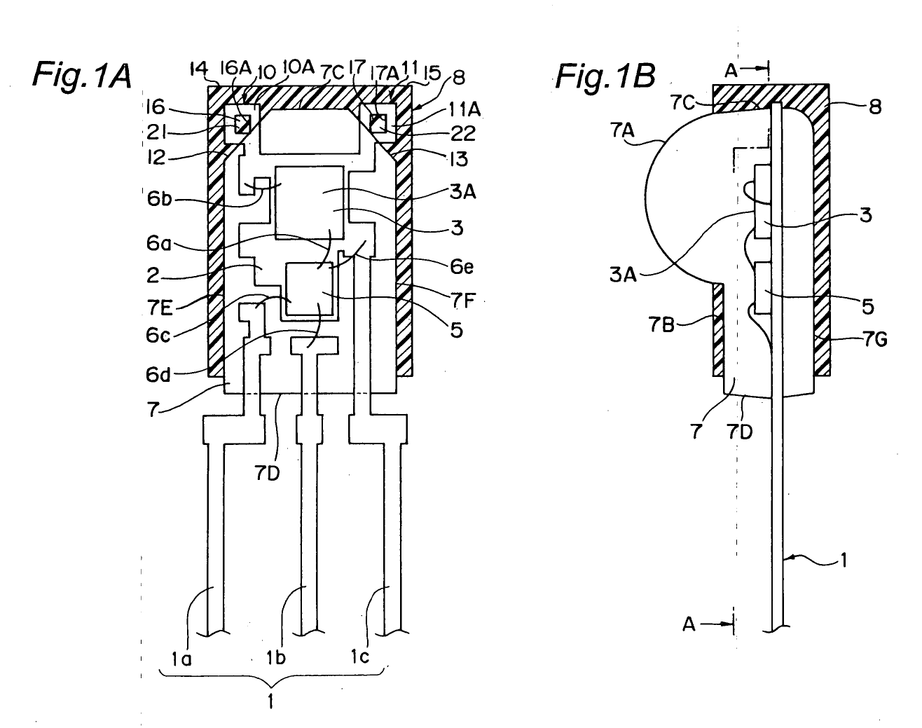

FIGS. 1A and 1B show the sectional construction. of one embodiment of the semiconductor device for optical communication. FIG. 1A is a sectional view taken along the line A-A′ in FIG. 1B.

The semiconductor device for optical communication has a lead frame 1 that includes a first lead 1a for a signal, a second lead 1b for a power supply and a third lead 1c for connection to the ground, a photodetector chip 3 that is the photodetector mounted on a mounting section 2 included by the third lead 1c for connection to the ground and a control. IC chip 5 that is the signal processing section. The photodetector chip 3 is constructed of a photodiode, a phototransistor or the like. Moreover, the control IC chip 5 has a built-in amplifier of a high gain.

The IC chip 5 and the photodetector chip 3 are connected together via a conductive wire 6a, and the photodetector chip 3 is connected to the third lead 1c via a conductive wire 6b. Moreover, the control IC chip 5 is connected to the first lead 1a via a conductive wire 6c, connected to the second lead 1b via a conductive wire 6d and connected to the third lead 1c via a conductive wire 6e.

The lead frame 1, the photodetector chip 3 and the control IC chip 5 are integrally fixed by a first sealing portion 7 fabricated of an infrared transmitting resin as the translucent resin, and the first sealing portion 7 seals the photodetector chip 3 and the control IC chip 5. The first sealing portion 7 has a convex light receiving lens portion 7A for guiding infrared light as a signal light in a portion of the exterior surface of the first sealing portion 7 facing a light receiving surface 3A of the photodetector chip 3. A front portion 7B, a top surface 7C, side surfaces 7E and 7F and a rear surface 7G, which are other than the light receiving lens portion 7A, of the exterior surface of the first sealing portion 7 are sealed in a second sealing portion 8 fabricated of a conductive resin described later. In FIGS. 1A and 1B, only the second sealing portion 8 is hatched. The reason why the second sealing portion 8 does not cover the bottom surface 7D is to prevent the occurrence of the electrical short circuit among the conductive resin that constitutes the second sealing portion 8, the first lead 1a for the signal and the second lead 1b for the power supply.

The lead frame 1 has approximately quadrangled extended portions 10 and 11 extended from inside the first sealing portion 7 into the second sealing portion 8. That is, the extended portions 10 and 11 are embedded in the second sealing portion 8. The extended portions 10 and 11 are arranged between chamfer portions 12 and 13 of the first sealing portion 7 and corner portions 14 and 15 of the second sealing portion 8. This arrangement allows the size reduction to be achieved by restraining an increase in the outside dimensions due to the existence of the extended portions 10 and 11.

Moreover, the surfaces 10A and 11A of the extended portions 10 and 11 are wholly put in close contact with the second sealing portion 8. Moreover, the extended portions 10 and 11 have through holes 16 and 17 that have inner surfaces 16A and 17A of a quadrangular prism shape. The through holes 16 and 17 are internally. filled with portions (conductive portions) 21 and 22 of the second sealing portion 8, and the conductive portions 21 and 22 are put in close contact with the inner surfaces 16A and 17A of the through holes 16 and 17.

In the semiconductor device for optical communication of the construction, if a signal light constituted of infrared light is made incident on the light receiving lens portion 7A of the first sealing portion 7, then the signal light is guided to the light receiving surface 3A of the photodetector chip 3. Then, the photodetector chip 3 converts the signal light into an electrical signal and outputs the electrical signal to the control IC chip 5 via the conductive wire 6a. Then, the control IC chip 5 outputs an output signal, which is obtained by subjecting the electrical signal to prescribed signal processing, to the first lead 1a via the conductive wire 6c. Moreover, the control IC chip 5 is connected to the second lead 1b via the conductive wire 6d. The second lead 1b is connected to the power supply of the board (not shown) in the mounted state, and an electric power is supplied from the power supply to the control IC chip 5 via the second lead 1b and the conductive wire 6d. Moreover, the control IC chip 5 is connected to the third lead 1c via the conductive wire 6e. The third lead 1c is connected to a ground (GND) terminal of the board.

The second sealing portion 8, which covers the first sealing portion 7 fabricated of the infrared transmitting resin, is fabricated of the conductive resin, and the second sealing portion 8 is wholly put in close contact with and electrically connected to the surfaces 10A and 10B of the extended portions 10 and 11 of the third lead 1c of the lead frame 1. Therefore, if the semiconductor device for optical communication is mounted on the board and the third the lead 1c is connected to the GND terminal, then the second sealing portion 8 plays the role of an electromagnetic noise shield for the photodetector chip 3 and the control IC chip 5 sealed in the first sealing portion 7. Moreover, the through holes 16 and 17 within the extended portions 10 and 11 of the lead frame 1 are filled with the conductive portions 21 and 22 of the second sealing portion 8, which are put in close contact with the peripheral surfaces 16A and 17A of the through holes 16 and 17. This therefore allows the increase in the contact area between the extended portions 10 and 11 and the second sealing portion 8 to be achieved and allows the electromagnetic noise shielding effect to be improved by improving the conductivity of the electrical connection between the extended portions 10 and 11 and the second sealing portion 8.

If conductivity is achieved by bringing the extended portions 10 and 11 in contact with the second sealing portion 8 as described above, it is not required to provide another member for grounding the second sealing portion 8. Therefore, the semiconductor device for optical communication can be fabricated at low cost, and the degrees of freedom of mounting on the board can be improved.

The semiconductor device for optical communication is basically manufactured through the following manufacturing processes i) through iv). That is, the device is manufactured through:
i) a die bonding process for mounting the photodetector chip 3 and the control IC chip 5 on the mounting section 2 of the lead frame 1 (third lead 1c);
ii) a wire bonding process for electrically connecting the photodetector chip 3, the control IC chip 5 and so on by wiring the conductive wires 6a through 6ein the manner described above;
iii) a first sealing process for fabricating the first sealing portion 7 made of the infrared transmitting resin by injecting the infrared transmitting resin to the periphery of the photodetector chip 3 and the control IC chip 5 by using a metal mold; and
iv) a second sealing process for fabricating the second sealing portion 8 made of the conductive resin by injecting the conductive resin to the periphery of the first sealing portion 7 by using a metal mold.

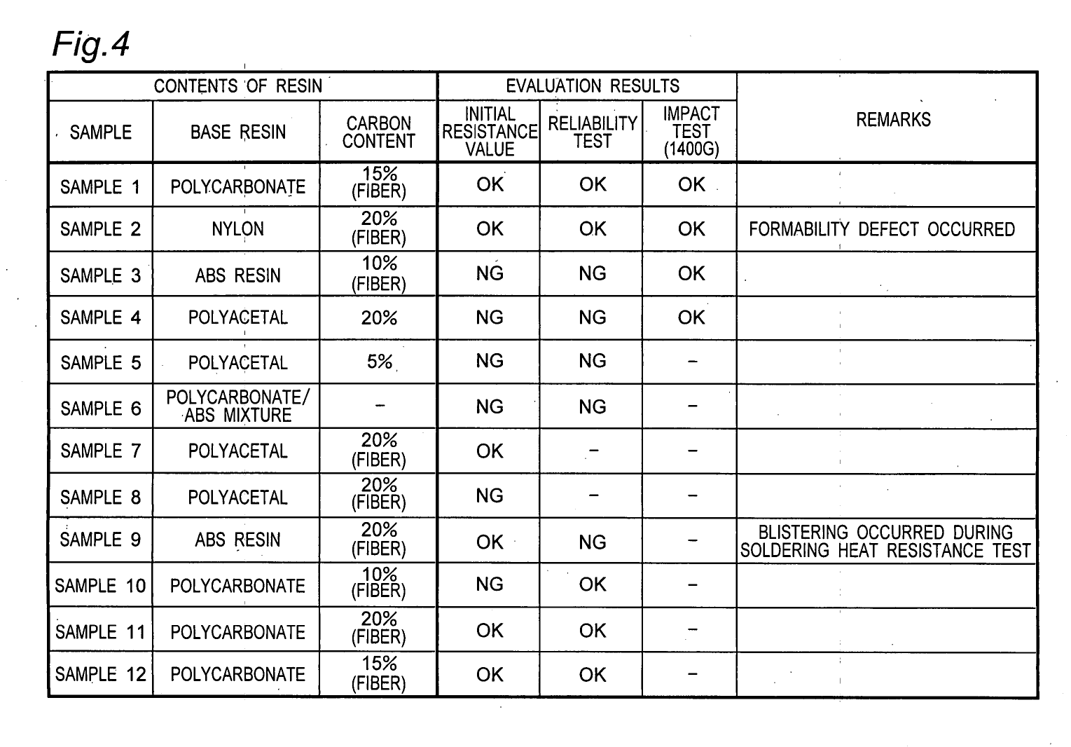

FIG. 4 shows the experimental results of the conductive resin that constitutes the second sealing portion 8 conducted through repetitive experiments by the present inventor with an intention to improve the productivity, electromagnetic noise shielding effect and reliability.

As shown in the section of the “contents of resin”, the present inventor prepared samples (Sample 1 through Sample 12) in which the conductive resin constituting the second sealing portion 8 was constituted of a base resin and a conductive additive, and the base resin and the conductive additive were variously changed. With regard to the base resin, polycarbonate, nylon, ABS resin (Acrylonitrile Butadiene Styrene Plastics), polyacetal and polycarbonate/ABS mixture (mixture of polycarbonate and ABS resin) were adopted. Moreover, the conductive additive was provided by a carbon fiber, and the content thereof was changed in steps of five points to 5%, 10%, 15% and 20%.

The samples were evaluated on the basis of the results of an initial resistance value (i.e., conductivity immediately after the production of the samples), a reliability test (65C, 95%, temperature cycle, exposed at high temperature) and an impact test (1400 G) as shown in the column of the “EVALUATION RESULTS”. The satisfactory evaluation results are indicated by a sign “OK”, and the defective results are indicated by a sign “NG”.

As is apparent from the evaluation results, the reliability test results of the samples 3, 4, 5, 6 and 9 of which the base resin is ABS resin, polyacetal or polycarbonate/ABS mixture are defective (NG). The sample 9, of which the base resin was ABS resin, had no problem about formability and conductivity, but the blistering of the resin occurred regarding the soldering heat resistance test (300° C., 15 seconds). The samples 4, 5 and 8, of which the base resin was polyacetal, exhibited poor conductivity between the lead frame 1 and the second sealing portion 8 (conductive resin).

In contrast to the above, the reliability test results of the samples 1, 2, 10, 11 and 12, of which the base resin was polycarbonate or nylon, are satisfactory. However, with regard to the sample 2, of which the base resin was nylon, some cases of defective formation occurred, or in concrete, there were some cases where the light receiving lens portion 7A was disadvantageously covered with the injected resin in the second sealing process. Moreover, with regard to the samples, of which the base resin was polycarbonate, the initial resistance value was defective (NG) in the case where the carbon fiber content was not higher than 10% (sample 10).

According to the evaluation results, it was discovered that, by making the conductive resin constituting the second sealing portion 8 have a base resin of polycarbonate and a conductive additive of a carbon fiber and setting the content thereof not lower than 15%, an excellent one having the features that:
(a) the formation of the conductive resin was satisfactory and the productivity was good;
(b) the conductivity of the conductive resin was good, so that the electromagnetic noise shielding effect was sufficient; and
(c) neither external appearance nor conductivity was changed (deteriorated) by heat and so on applied during mounting or, in particular, at the time of soldering was obtained. Moreover, the degrees of freedom of mounting on the board can be improved by virtue of the small size and low cost in comparison with the case where shield is provided by using a metal shield casing.

The carbon fiber content of the conductive additive should preferably be not higher than 30% from the viewpoint of making the formability of the second sealing portion 8 satisfactory.

Although carbon black and stainless steel were examined as the conductive additive besides the carbon fiber, the additives other than the carbon fiber exhibited poor conductivity in the present shape.

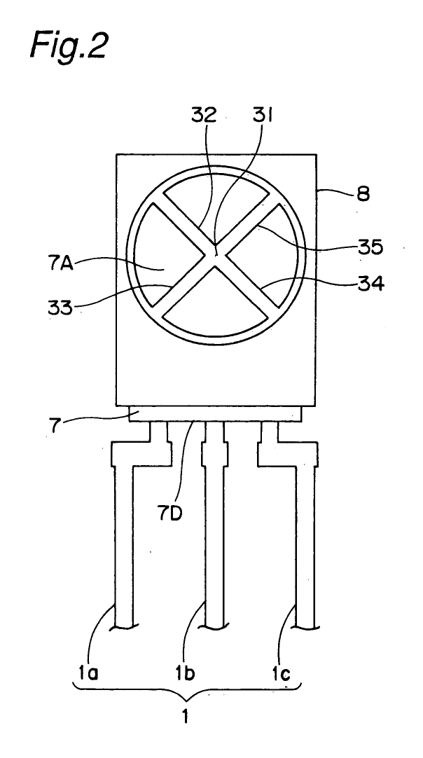

FIG. 2 shows a modification example of the semiconductor device for optical communication viewed from the front (on the light incident side). In this modification example, the second sealing portion 8 has a mesh section 31 that covers the convex surface of the light receiving lens portion 7A in a mesh form. In this example, the mesh section 31 is constructed of four elements 32, 33, 34 and 35, which are extended from the peripheral edge portions of the light receiving lens portion 7A and concentrated on the vertex. The four elements 32, 33, 34 and 35 are arranged at regular angular intervals so that the electromagnetic noise shielding can be satisfactorily achieved.

In the semiconductor device for optical communication, the mesh section 31 of the second sealing portion 8 covers the convex surface of the light receiving lens portion 7A in a mesh form. Therefore, light (infrared rays or the like) can be made incident on the photodetector chip 3 through the intervals (meshes) of the mesh section 31 and the light receiving lens portion 7A, while the electromagnetic noises can be shielded by the mesh section 31 made of the conductive resin. Therefore, the semiconductor device for optical communication can be suited to the environment where large electromagnetic noises exist. Moreover, part of the second sealing portion 8 constitutes the mesh section 31, and therefore, the semiconductor device for optical communication is manufactured at lower cost than in the case where another member like a metal mesh is employed.

The number of elements of the mesh section 31 may be greater, but it is necessary to restrict the number within the extent that the numerical aperture is not excessively lowered as a consequence of narrowed intervals (meshes).

The semiconductor device for optical communication of FIG. 2 is basically manufactured through the same processes as the manufacturing processes i) through iv) of the semiconductor device for optical communication of FIGS. 1A and 1B.

However, it is generally difficult to fabricate the mesh section 31 by resin molding because the mesh section 31 has the mesh form that is minute and curved along the convex surface of the light receiving lens portion 7A. The above is because, when the resin is injected into the metal mold as the mold, bubbles are left in meshed grooves of the mold which are corresponding to the mesh section, and the resin hardly enters the grooves.

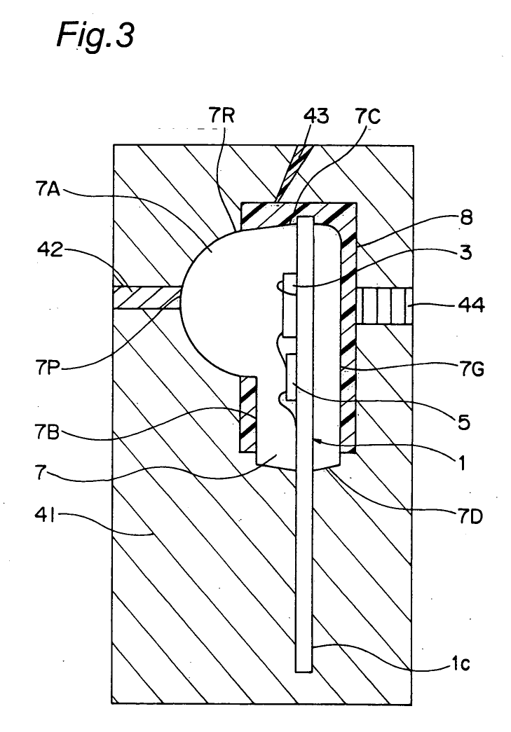

Accordingly, as shown in FIG. 3, the present embodiment devises a metal mold 41 used in the second sealing process. The detail is as follows.

First of all, the metal mold 41 has a liner 42 in a portion corresponding to the vertex 7P of the light receiving lens portion 7A. With this arrangement, air escapes from a minute gap between the main body of the metal mold 41 and the liner 42 when the conductive resin is injected into the metal mold 41 in the second sealing process. Therefore, the conductive resin successfully flows around the periphery of the light receiving lens portion 7A, and the mesh section 31 is accurately formed.

Moreover, the metal mold 41 has a resin injection gate 43 facing the light receiving lens portion 7A on the top surface 7C side of the first sealing portion 7, and the resin injection gate 43 is inclined back and forth so as to inject the resin in a direction from a peripheral edge portion 7R to the vertex 7P of the light receiving lens portion 7A. With this construction, the resin injection gate 43 faces the light receiving lens portion 7A in a comparatively nearby position on the side opposite from the bottom surface 7D from which the signal input and output terminals 1c and so on constructed of part of the lead frame 1 project. Therefore, when the conductive resin is injected into the metal mold 41 in the second sealing process, the conductive resin easily flows around the periphery of the light receiving lens portion 7A. Therefore, the fabrication accuracy of the mesh section 31 is improved.

As described above, by devising the metal mold 41 used in the second sealing process, the semiconductor device for optical communication shown in FIG. 2 can be accurately manufactured.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor device for optical communication, comprising:
a lead frame;
a photodetector mounted on the lead frame;
a signal processing section that is mounted on the lead frame and electrically connected to the photodetector;
a first sealing portion that is fabricated of a translucent resin and seals the photodetector and the signal processing section; and
a second sealing portion that is fabricated of a conductive resin and covers the first sealing portion, wherein the conductive resin constituting the second sealing portion is made of polycarbonate and a conductive additive.

2. The semiconductor device for optical communication as claimed in claim 1, wherein
the conductive additive is a carbon fiber.

3. The semiconductor device for optical communication as claimed in claim 2, wherein
the conductive resin has a carbon fiber content of not lower than 15%.

4. The semiconductor device for optical communication as claimed in claim 1, wherein
a convex light receiving lens portion is provided in a portion of an exterior surface of the first sealing portion facing the photodetector, and
the second sealing portion has a mesh section that covers a convex surface of the light receiving lens portion in a mesh form.

5. A method for manufacturing a semiconductor device for optical communication, comprising:
mounting a photodetector and a signal processing section on a lead frame and electrically connecting the signal processing section to the photodetector;
fabricating a first sealing portion that is made of a translucent resin and has a convex light receiving lens portion by sealing the photodetector and the signal processing section with the translucent resin; and
fabricating a second sealing portion that is made of a conductive resin and has a mesh section for covering a convex surface of the light receiving lens portion in a mesh form by injecting the conductive resin to a periphery of the first sealing portion by using a mold,
the mold having a liner in a portion corresponding to a vertex of the light receiving lens portion.

6. A method for manufacturing a semiconductor device for optical communication, comprising:
mounting a photodetector and a signal processing section on a lead frame and electrically connecting the signal processing section to the photodetector;
fabricating a first sealing portion that is made of a translucent resin and has a convex light receiving lens portion by sealing the photodetector and the signal processing section with the translucent resin; and
fabricating a second sealing portion that is made of a conductive resin and has a mesh section for covering a convex surface of the light receiving lens portion in a mesh form by injecting the conductive resin to a periphery of the first sealing portion by using a mold,
the mold having a resin injection gate facing the light receiving lens portion on a side opposite from a surface from which signal input and output terminals comprised of part of the lead frame project outwardly of the first sealing portion.

7. The semiconductor manufacturing method as claimed in claim 6, wherein
the resin injection gate is inclined back and forth so as to inject a resin in a direction from a peripheral edge portion to a vertex of the light receiving lens portion.
